(19) United States
(12) Patent Application Publication
(10) Pub. No.: US 2013/0119506 A1
(43) Pub. Date: May 16, 2013

(54) FORMATION OF STI TRENCHES FOR LIMITING PN-JUNCTION LEAKAGE

(71) Applicant: Akira Hokazono, Kawasaki (JP)

(72) Inventor: Akira Hokazono, Kawasaki (JP)

(73) Assignee: TOSHIBA AMERICA ELECTRONIC COMPONENTS, INC., Irvine, CA (US)

(21) Appl. No.: 13/293,269

(22) Filed: Nov. 10, 2011

(51) Int. Cl. H01L 23/00

(52) U.S. Cl. 257/506; 257/E23.002

(57) ABSTRACT

Methods and structure are provided to facilitate isolation of respective ground plane regions in an SOTB semiconductor device. In one aspect a shallow STI trench can be combined with Si:C or Si:C/SiGe layers to confine n-type and p-type regions. In a further aspect, Ge can be implanted at the bottom of a shallow STI trench and subsequently oxidized to form SiGe oxide thereby extending the effective isolation provided by the shallow STI trench. In an aspect, a shallow STI trench can be extended to expose an underlying layer of SiGe, wherein the SiGe is subsequently oxidized to extending the effective isolation provide by the shallow STI trench. Such aspects enable a shallow STI trench to be seamlessly filled while having an extended region of isolation.

### FIELD

Embodiments described herein relate generally to methods and systems for extending the effective depth of shallow trench isolation structures.

### BACKGROUND

Silicon large-scale integrated circuits, among other device technologies, are increasing in use in order to accommodate the advanced information society of today and the future. An integrated circuit may be composed of a plurality of semiconductor devices, such as transistors or the like, which can be produced according to a variety of techniques. To continuously increase integration and speed of semiconductor devices, a trend of continuously scaling semiconductors (e.g., reducing size and features of semiconductor devices) has emerged. Reducing semiconductor and/or semiconductor feature size provides improved speed, performance, density, cost per unit, etc., of resultant integrated circuits. However, as semiconductor devices and device features have become smaller, conventional fabrication techniques have been limited in their ability to produce finely defined features.

One concern associated with reduced device features is the effect of pn-junction leakage. As respective doped p-type and n-type regions reside with closer proximity to each other, the likelihood of pn-junction leakage increases. One technology to facilitate separation of doped regions from each other is shallow trench isolation (STI), wherein a STI structure is utilized to isolate respective doped regions (e.g., p-type from n-type, etc.). STI involves creating an isolating trench, depositing an isolating material (e.g., an oxide) into the trench, followed by removal of any excess material, as necessary. However, as device patterning dimensions continue to diminish in size, the ability to completely fill a trench with material is not always achievable, especially with a degree of consistency required in semiconductor manufacturing processes. Hence, while technologies facilitate further miniaturization of semiconductor related devices and components, issues regarding employing STI techniques in such devices and components are still to be addressed.

### SUMMARY

A simplified summary is provided herein to help enable a basic or general understanding of various aspects of exemplary, non-limiting embodiments that follow in the more detailed description and the accompanying drawings. This summary is not intended, however, as an extensive or exhaustive overview. Instead, the sole purpose of this summary is to present some concepts related to some exemplary non-limiting embodiments in a simplified form as a prelude to the more detailed description of the various embodiments that follow.

In an exemplary, non-limiting embodiment, a first layer comprising Si:C and a second layer comprising SiGe are utilized to limit the extent to which a ground plane GP extends through a substrate (e.g., a Si substrate). An STI can be formed, e.g., by etching, having such a depth to contact the Si:C layer. The Si:C layer acts to suppress diffusion of B, In, or P elements while the SiGe layer acts to suppress diffusion of B and In elements. Hence the GP is confined between a BOX layer and the Si:C/SiGe layers. In a further exemplary, non-limiting embodiment, owing to Si:C suppressing diffusion of B, In, and P, Si:C can be utilized in isolation to control p-type and n-type regions, and only a layer of Si:C is required as opposed to a combination of Si:C/SiGe layers.

In a further exemplary, non-limiting embodiment, a region of Si located at the bottom of a STI trench is implanted with Ge to form a SiGe rich region. In an exemplary, non-limiting embodiment, the SiGe rich region can be contiguous with an underlying SiGe layer. Oxidizing conditions can be established to facilitate formation of SiGe oxide both in the SiGe rich region and the underlying SiGe layer. Formation of the SiGe oxide acts to effectively extend the isolating properties of the STI trench (as subsequently filled with isolating material). Further, the inverted T-shape of SiGe oxide obtained at the bottom of the STI trench improves isolation properties of the STI trench owing to the effective increased width of the STI trench and furthermore the rounded nature of the SiGe oxide reduces stress at the base of the STI trench further improving the isolation properties of the STI trench.

In another exemplary, non-limiting embodiment, a STI trench can be extended to expose an underlying layer of SiGe. An oxidizing atmosphere can be established thereby facilitating the formation of SiGe oxide of the exposed SiGe at the bottom of the STI trench. The SiGe oxide effectively extends the structure of the STI trench and engendered isolating properties.

### BRIEF DESCRIPTION OF THE DRAWINGS

FIG. 1 is a block diagram of an exemplary SOTB structure according to an embodiment of the subject innovation.

FIG. 2 illustrates block diagrams of isolating trench structures formed by single-trench STI and double-trench STI processes in association with embodiments of the subject innovation.

FIG. 3 illustrates a defect arising from incomplete fill of an STI trench in association with embodiments of the subject innovation.

FIG. 4 presents exemplary block diagrams illustrating use of Si:C and SiGe layers to confine a group plane according to one or more embodiments of the subject innovation.

FIG. 5 illustrates a flow for utilizing Si:C and SiGe layers to confine a group plane in accordance with one or more embodiments of the subject innovation.

FIG. 6 presents exemplary block diagrams illustrating use of Ge implantation and oxidation of SiGe for producing a STI trench according to one or more embodiments of the subject innovation.

FIG. 7 illustrates a flow for utilizing Ge implantation and oxidation of SiGe layers to extend the depth of an STI trench in accordance with one or more embodiments of the subject innovation.

FIG. 8 illustrates exemplary block diagrams illustrating use of oxidation of SiGe to extend the depth of an STI trench according to one or more embodiments of the subject innovation.

FIG. 9 illustrates a flow for utilizing SiGe oxidation to extend the depth of an STI trench in accordance with one or more embodiments of the subject innovation.

### DETAILED DESCRIPTION

Presented herein are various techniques and structures relating to utilizing STI technology in semiconductor devices and components. As described in the background, STI technology can be utilized to isolate respective regions of a semiconducting device as part of the manufacturing process and final component design. However, as device patterning dimensions continue to diminish in size, the ability to seamlessly fill an STI trench with oxide material is not always achievable, especially with a degree of repeatability and consistency required in semiconductor manufacturing processes.

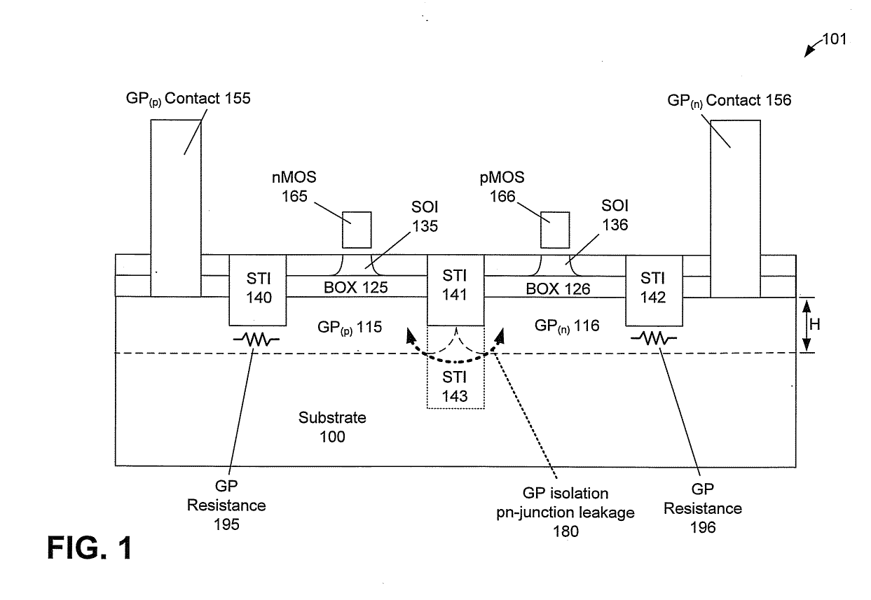

FIG. 1 illustrates a silicon-on-thin-buried oxide (SOTBOX, also known as a silicon-on-thin-BOX (SOTB)) device comprising shallow trench isolation (STI) technology. Respective ground planes (GP) are formed on substrate 100 by p-type doping (GP(p) 115) and n-type doping (GP(n) 116). For example, GP(p) 115 can be formed by doping with boron or indium, while GP(n) 116 can be formed by doping with phosphorous. Above the GP's are layers comprising a buried oxide (BOX) layer which is formed by isolation into BOX 125 and BOX 126 respectively associated with metal-oxide-semiconductors nMOS 165 and pMOS 166. The respective silicon-on-insulators, SOI's 135 and 136, combine with BOX's 125 and 126 to create a silicon-on-insulator (SOI) MOSFET, SOTB. In one aspect, creation of the SOTB can comprise of an ultra-thin layer of BOX 126 to facilitate operation of the SOTB. Further, the SOI can be partially depleted SOI (PDSOI) or fully depleted SOI (FDSOI), wherein the thickness of various layers comprising the SOTB can be a function of the depletion region. For example, a thick film can be utilized by a PDSOI to prevent the depletion layer covering a whole film, and a thin film in a FDSOI enabling the depletion layer to cover the whole film.

Connected to GP(p) 115 is contact 155, and connected to GP(n) 116 is contact 156. Operation of the SOTB device is conducted based on operation of the nMOS 165 [symbol] GP(p) contact 155, and pMOS 166 [symbol] GP(n) contact 156. STI 141 is utilized to isolate the GP(p) 115 from GP(n) 116, however pn-junction leakage 180 can occur beneath STI 141.

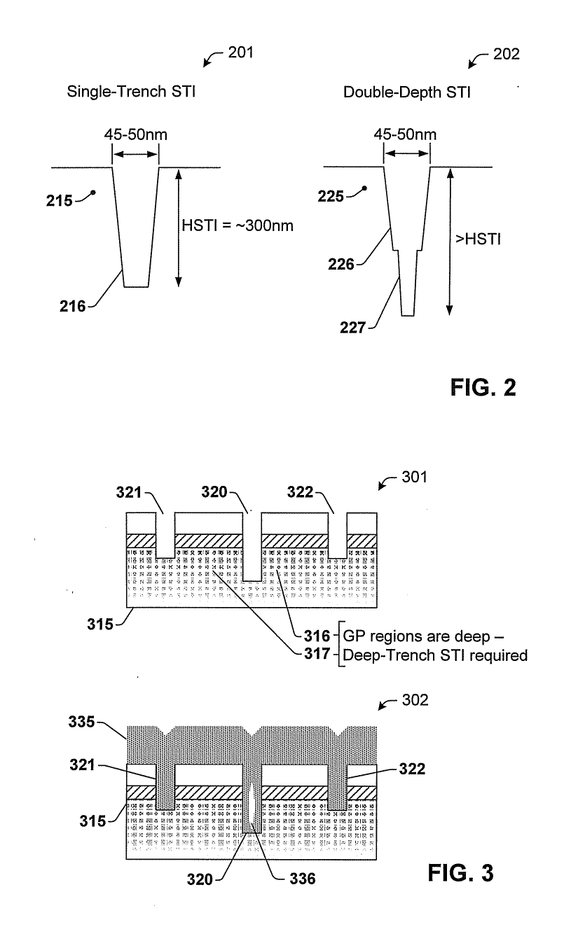

A number of technologies have been developed to minimize pn-junction leakage 180, such as increasing the depth of the isolating trench. As shown in FIG. 1, the shallow depth of STI 141 can be extended to the deep depth of STI 143. Turning to FIG. 2-201, single-trench technology can be utilized to facilitate formation of a trench 216 (e.g., a shallow trench STI 141) in substrate 215. While a trench can be formed with dimensions based upon the operating conditions during formation of the trench, a single-trench STI is typically limited to an opening of about 45-50 nm and a depth (HSTI) of about 300 nm. As shown in FIG. 2-202, double-depth STI technology can be utilized to form a deeper trench (e.g., deep trench STI 143) than typically obtainable by single-trench technology, where trenches 226 and 227 are formed in substrate 225 as part of a two stage process. As shown, the depth of the trench formed by the two stage process of forming trenches 226 and 227 enables a trench to be formed with a depth greater than that achievable by the single-trench STI technology, i.e., the double-depth trench is deeper than HSTI. However, such double-depth STI technologies (also known as deep-trench STI and double-trench STI technologies) incur increased process costs, for example, associated with ensuring that the deep trench is seamlessly filled during material deposition, e.g., with SiO₂.

It is to be appreciated that while substrates 215 and 225 are depicted as comprising a single, continuous structure, such depiction is for illustrative purposes only and substrates 215 and 225 can comprise a plurality of layers (e.g., monolithic Si substrate, BOX, SOI, etc.).

As shown in FIG. 3-301, the ground plane (GP) regions 316 and 317 can extend into substrate 315 to such a depth that a deeper trench 320 (e.g., a double-depth STI trench) is required to isolate the respective regions 316 and 317, while ancillary trenches 321 and 322 can be formed using single-trench STI technology. However, as illustrated in FIG. 3-302, during deposition of trench fill material 335 (e.g., an oxide, SiO, etc.) shallow trenches 321 and 322 are able to be filled completely, but owing to physical constraints encountered during deposition, voids 336 may occur during filling of double depth trench 320 owing to shrinkage, insufficient ingress of material, or other effect encountered during the deposition process, thereby minimizing the ability to seamlessly fill the trench. Hence, while SOTB technologies facilitate further miniaturization of semiconductor related devices and components, issues regarding employing STI techniques in SOTB are still to be addressed. By utilizing the various exemplary, non-limiting embodiments presented herein it is possible to achieve a ‘trench’ of sufficient material and consistency to facilitate isolation of respective regions of the semiconductor device.

The following description and the annexed drawings set forth certain illustrative aspects of the specification. These aspects are indicative, however, of but a few of the various ways in which the principles of the specification may be employed. Other advantages and novel features of the specification will become apparent from the following detailed description of the disclosed information when considered in conjunction with the drawings.

The claimed subject matter is now described with reference to the drawings, wherein like reference numerals are used to refer to like elements throughout. In the following description, for purposes of explanation, numerous specific details are set forth in order to provide a thorough understanding of the claimed subject matter. It may be evident, however, that the claimed subject matter may be practiced without these specific details. In other instances, well-known structures and devices may be shown in block diagram form in order to facilitate describing the claimed subject matter.

Throughout the description, a silicon-germanium (SiGe) material is referenced, wherein the material can be of any molar ratio of Si and Ge, and typically can be expressed as an alloyed Si₁₋ₓGeₓ. Further, it is to be appreciated that while the various concepts presented herein are described in reference to particular materials, e.g., Si, Si:C, SiGe, SiGe oxide, oxide, etc., the referenced materials are to be considered exemplary and the presented concepts can be utilized in reference to any materials for which the presented concepts are applicable. It is to be further appreciated that while only a single layer of dielectric, insulator, organic film, etc., is typically presented as part of a layered structure, a single layer can comprise of a plurality of layers. For example, a single dielectric or single organic film can be replaced with a plurality of layers comprising a dielectric layer, interlayer dielectric (ILD), a low k polymer layer, organic film, patterning film, carbon film, etc.

The term dielectric is employed to describe a material having insulating properties being utilized to separate other layers, and can include one or more materials considered to be dielectrics, insulators, etc. In effect, to facilitate description of the various embodiments presented herein the term dielectric is employed to indicate a layer having dielectric or insulative properties compared with the conductive properties of a metal line, metallization layer, etc. Hence, while the term dielectric is employed throughout the description, it is to be appreciated that the term dielectric does not limit a layer to be comprised of dielectric material, rather the layer can comprise of an insulator, or other material acting as a separation layer, wherein separation can either be provided spatially or in terms of a material property, such as provides electrical separation between layers.

Dielectrics can include materials such as an insulative oxide layer, silicon dioxide, silicon oxynitride, boronitride, silicon boronitride and silicon carbide. Dielectric layer(s) can also comprise low k inorganic materials and low k polymer materials including polyimides, fluorinated polyimides, polysilsequioxane, benzocyclobutene (BCB), parlene F, parlene N and amorphous polytetrafluoroethylene. A specific example of a commercially available low k polymer material is Flare™ from AlliedSignal believed to be derived from perfluorobiphenyl and aromatic bisphenols. Low k polymer materials provide electrical insulation between various layers, devices and regions within semiconductor substrates.

Further, layers comprising any of organic film, patterning film, carbon film, or the like, can be utilized to facilitate formation of the STI trenches, Ge implantation, SiGe oxidation, etc. Such films can be of any suitable material, e.g., cyclopentene, pyroline, norbornadiene, etc., and of any suitable thickness as to facilitate formation of the structures presented herein.

Further, a dielectric film, insulative film, organic film, etc., may be formed to any suitable thickness using any suitable technique, for instance, using chemical vapor deposition (CVD) techniques. CVD techniques include low pressure chemical vapor deposition (LPCVD) or plasma enhanced chemical vapor deposition (PECVD). In an exemplary, non-limiting embodiment, dielectrics, organic films, etc., presented herein can be employed as an etch stop layer as part of the patterning of a mask layer, resist layer, etc. A particular etch can be utilized to remove a particular layer of dielectric or organic film, while a different etch is required to facilitate patterning of the mask, resist, etc. By utilizing different etching processes (e.g., different etchants) desired portions of a particular layer can be removed while portions of a disparate layer are left intact. It is to be further appreciated that while only a single layer dielectric, insulator, or organic film is typically shown, such a layer can comprise of a plurality of layers. For example, a single dielectric, single insulating film, or single organic film can be replaced with a plurality of layers comprising a dielectric layer, interlayer dielectric (ILD), a low k polymer layer, organic film, patterning film, insulator, carbon film, etc.

Any suitable technique can be used to pattern any of the material layers presented herein, (e.g., dielectric, insulator, patterning film, organic film, carbon film, hard mask, etc.). For example, patterning can be created by employing a photoresist which is patterned using standard photolithographic techniques to form the required pattern to create the pattern, trenches, openings, etc., wherein the photoresist is exposed to electromagnetic radiation through a mask having an image pattern of a desired layout (e.g., desired trenches, openings, line patterning, etc.). Openings are then formed in the photoresist in order to form the desired layout, e.g., by etching away the exposed material (in the case of a positive photoresist) or etching away the unexposed material (in the case of a negative photoresist). Depending on the material of the photoresist, exposure can create a positive or a negative. With a positive photoresist, exposure causes a chemical change in the photoresist such that the portions of the photoresist layer exposed to light become soluble in a developer. With a negative photoresist, the chemical change induced by exposure renders the exposed portions of the photoresist layer insoluble to the developer. After exposure and develop, a layout according to the desired pattern is laid out on the first layer. A subsequent processing step, such as an etching step or an ion implantation step, can be performed and controlled according to the layout. For instance, after exposure and developing, material in a layer not covered by the photoresist layer can be etched, thus transferring the pattern to the layer. The photoresist can be subsequently removed. Etching can be by any viable dry or wet etching technique. For example, a wet or dry etching technique can be employed for patterning, while in another aspect, etching can be by a specific anisotropic etch. An etching technique of particular applicability to the various material processes herein is reactive-ion etching (RIE). In another aspect, plasma ashing can be employed to remove various material layers, photoresists, organic films, etc.

Levelling of layers after formation can be by any suitable technique, e.g., by chemical metal polish (CMP) or other suitable process, in preparation for the next stage in creation of the multilayer stack.

Further, mask layers can comprise of titanium nitride (TiN), or any other suitable material such as TaN, silicon dioxide, silicon nitride, silicon oxynitride, boronitride, silicon boronitride, silicon carbide, and the like, and formed by any suitable technique such as chemical vapor deposition (CVD) or spin-on methods.

It is to be appreciated that while the formation of the various layers, elements, etc., comprising the stack are described, along with formation of an STI trench(es) there may be certain procedures that are not fully disclosed during description of the various embodiments as presented herein. However, rather than provide description of each and every operation involved in the various operations facilitating formation, patterning, removal, etc., of each layer presented herein, for the sake of description only the general operations are described. Hence, while no mention may be presented regarding a particular operation pertaining to aspects of a particular figure, it is to be appreciated that any necessary operation, while either not fully disclosed, or not mentioned, to facilitate formation/deconstruction of a particular layer/element/aspect presented in a particular figure is considered to have been conducted. For example, while no mention may be made regarding an aspect involved in formation of a layer, trench, etc. (e.g., by deposition, spin forming, implantation, etching, leveling, etc.) it is considered, for the sake of readability of the various exemplary embodiments presented herein, that any required process has occurred, as have any other necessary operations. It is to be appreciated that the various operations, e.g., leveling, chemical metal polish, patterning, photolithography, spin coating, deposition, etching, RIE etch, etc., are well known procedures and are not necessarily expanded upon throughout this description.

Utilizing an Si:C layer to contain GP layer(s)

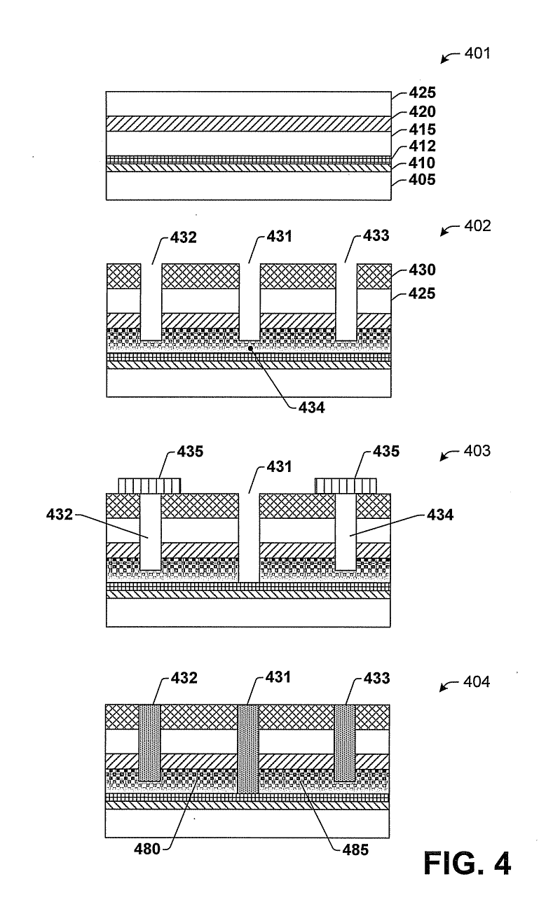

FIG. 4 illustrates an exemplary, non-limiting embodiment for formation of a SOTB device utilizing Si:C and SiGe layers in combination with extension of a single-trench STI to confine a GP layer(s) between a BOX layer and the Si:C/SiGe combination. Using the Si:C/SiGe layer enables a shallower deep trench STI to be used owing to the Si:C/SiGe layers suppressing diffusion of respective elements/ions. Utilizing an Si:C layer suppresses diffusion of boron (B), indium (In) and phosphorus (P) while utilizing an SiGe layer further suppresses diffusion of B and In, wherein a GP layer comprising P can be n-type and a GP layer comprising B and/or In can be p-type.

As illustrated in stage 401, a plurality of layers are deposited/formed. On a substrate 405 (e.g., comprising of Si) an SiGe layer 410 is deposited, over which is further deposited a Si:C layer 412. Above these layers, an Si layer 415 is formed, followed by formation of thin BOX 420 and SOI layer 425.

At stage 402, a masking layer 430 is deposited on to SOI layer 425, patterned and etched to subsequently form single-trenches 431, 432, and 433. It is to be noted that trenches 431, 432, and 433 do not extend to contact Si:C layer 610, rather Si material exists at the base of each trench, particularly in region 434 of trench 431.

At stage 403, further removal of material in trench 431 occurs. Owing to the desired removal of material being required at the base of trench 631, (e.g., region 434) resists 435 are formed over trenches 432 and 433 to prevent unnecessary etching of these trenches. Material in region 434 is removed until Si:C layer 412 is exposed.

At stage 404, resists 435 can be removed thereby enabling all of the trenches 431, 432, and 433 to be exposed and ready for subsequent filling with an isolating material (e.g., with oxide). As previously mentioned, the Si:C/SiGe layers confine the GP region, thereby enabling a shallower deep trench (i.e., trench 431) to be utilized in comparison with structures having an unconfined GP region. Owing to the isolation by trench 431 GP regions can operate as respective p-type or n-type regions, e.g., region 480 can be either a GP(p) region or a GP(n) region while region 485 can be the corresponding/alternate GP(p) region or GP(n) region. It is to be appreciated that while the various embodiments presented above comprise SiGe layer 410 and Si:C layer 412, a single layer comprising Si:C can be present to suppress diffusion of P in an n-type region and B and In in a p-type region. The operation of the SiGe layer in suppressing B and In for a p-type region can be supplemented by using the Si:C layer suppressing P in an n-type region.

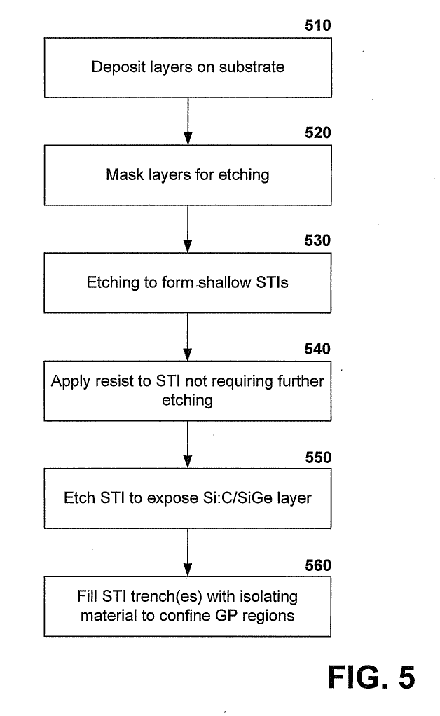

FIG. 5 presents a flow diagram illustrating an exemplary, non-limiting embodiment for confining respective GP(p) and GP(n) regions in an SOTB device. Extension of a single-trench STI to confine respective GP layers between a BOX layer and the Si:C/SiGe combination layer is presented. Utilizing an Si:C/SiGe layer enables a shallower trench STI to be used owing to the Si:C/SiGe layers suppressing diffusion of respective elements/ions. Utilizing an Si:C layer suppresses diffusion of boron (B), indium (In) and phosphorus (P) while utilizing an SiGe layer further suppresses diffusion of B and In, wherein a GP layer comprising P can be n-type and a GP layer comprising B and/or In can be p-type. Hence, owing to the combination of extending a shallow STI trench (e.g., trench 431) in combination with a Si:C/SiGe combination layer enables isolation of respective GP(p) and GP(n) regions without having to resort to double-depth STI techniques and to incur deleterious issues associated therewith.

At 510, a plurality of layers are deposited/formed to create the basic layered structure of the SOTB device. On a base substrate (e.g., substrate 405) comprising of any suitable material (e.g., Si) a layer of SiGe is formed (e.g., layer 410) along with a Si:C layer (e.g., layer 412). Above this layer, an Si layer (e.g., layer 415) is formed, followed by formation of thin BOX (e.g., thin BOX 420) and an SOI layer (e.g., SOI layer 425).

At 520, a masking layer (e.g., masking layer 430) is deposited on to the SOI layer and patterned as required to facilitate subsequent etching to form the required STI trenches (e.g., trenches 431, 432, and 433).

At 530, etching of the SOI layer, thin BOX layer, and Si layers is conducted to form the STI trenches. Etching is performed such that the STI trenches (e.g., trenches 431, 432, and 433) are of such a depth that they can be seamlessly filled with oxide thereby acting as isolation structures (note the depth of trench 431 is to be extended as described further).

At 540 resist is applied to isolate the trench requiring further etching (e.g., trench 431) from the trenches already at required depth (e.g., trenches 432 and 433).

At 550 the isolated trench is etched until the underlying Si:C layer (e.g., layer 410) is exposed.

At 560 the STI trenches (e.g., trenches 431, 432, and 433) can be filled with any suitable material (e.g., oxide) to facilitate formation and operation of the respective isolating structures. The Si:C/SiGe layers confine the GP region, thereby enabling a shallower trench (i.e., trench 431) to be utilized in comparison with structures having an unconfined GP region. Owing to the isolation by the trench in conjunction with the confining effect provided by the Si:C/SiGe layers, the GP regions (e.g., GP regions 480 and 485) can operate as respective p-type or n-type regions. For example, the first GP region (e.g., region 480) can be either a GP(p) region or a GP(n) region while the second GP region (e.g., region 485) can be the corresponding/alternate GP(p) region or GP(n) region.

Fabricating an Isolating Trench with Ge Implantation and SiGe Oxidation.

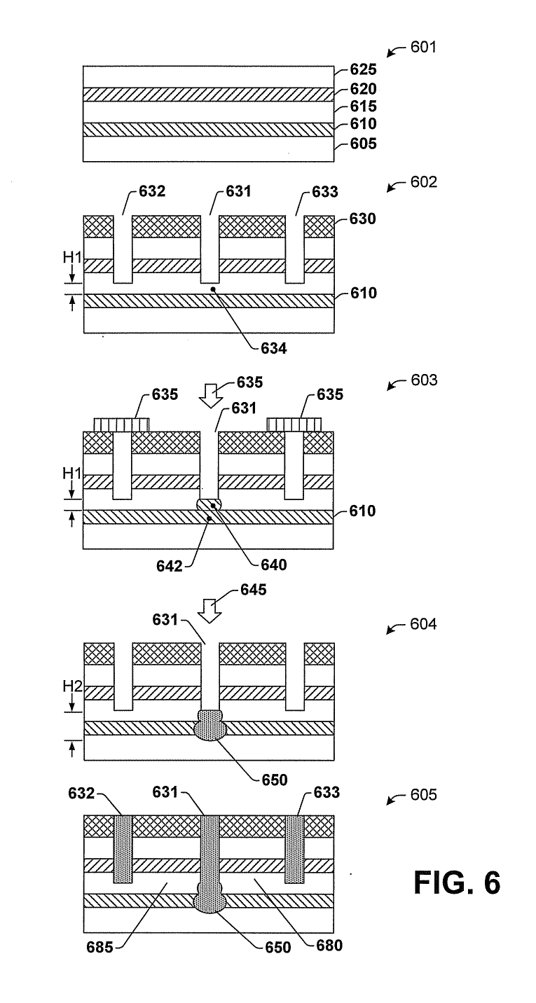

FIG. 6 illustrates an exemplary, non-limiting embodiment for formation of a SOTB device utilizing implantation of Ge at the bottom of a single-trench STI and subsequently oxidizing the implanted Ge to form SiGe oxide, thereby facilitating formation of a trench as part of an STI technique. As illustrated in stage 601, a plurality of layers are deposited/formed. On a substrate 605 (e.g., comprising of Si) an SiGe layer 610 is deposited. Above the SiGe layer, an Si layer 615 is formed, followed by formation of thin BOX layer 620 and SOI layer 625.

At stage 602, a masking layer 630 is deposited on to SOI layer 625, patterned and etched to subsequently form single-trenches 631, 632, and 633. It is to be noted that trenches 631, 632, and 633 do not extend to contact SiGe layer 610, rather Si material exists at the base of each trench, particularly in region 634 of trench 631. The height H1 of the material in region can be of any suitable amount, where a height in the range of about 10-30 nm is typical.

At stage 603, Ge implantation occurs at the base of trench 631. Owing to implantation only being required at the base of trench 631, resists 635 are formed over trenches 632 and 633 to prevent unnecessary implantation. Region 634 is implanted with Ge such that region 640 is created being an Si region rich in Ge, SiGe. It is to be noted that the SiGe region 640 is effectively contiguous with SiGe layer 610, region 642.

At stage 604, an oxidizing environment 645 is created with respect to trench 631. Owing to the oxidizing atmosphere, oxidation of SiGe region 640 occurs along with the portion of SiGe 642 in layer 610 residing beneath region 640. The oxidizing atmosphere results in the formation of SiGe oxide 650 at the base of trench 631. Depending upon the various conditions for oxidation, thickness of layer 610, height of material in 640, the volume of SiGe oxide 650 produced can be of any associated volume, wherein height H2 can be of any suitable amount, where height H2 in the range of 15-70 nm can be produced.

At stage 605, STI trenches 631, 632, and 633 can be filled with a suitable isolating material (e.g., an oxide) to facilitate formation of the isolating trench structures. In comparison with trenches formed using a double-depth process (e.g., as shown in FIG. 2-202) the respective trenches 631, 632, and 633 can be seamlessly filled with a degree of operational consistency and repeatability as required in high volume semiconductor device manufacture. Owing to the isolation by trench 631 and oxide region 650, GP regions can operate as respective p-type or n-type regions, e.g., region 680 can be either a GP(p) region or a GP(n) region while region 685 can be the corresponding/alternate GP(p) region or GP(n) region.

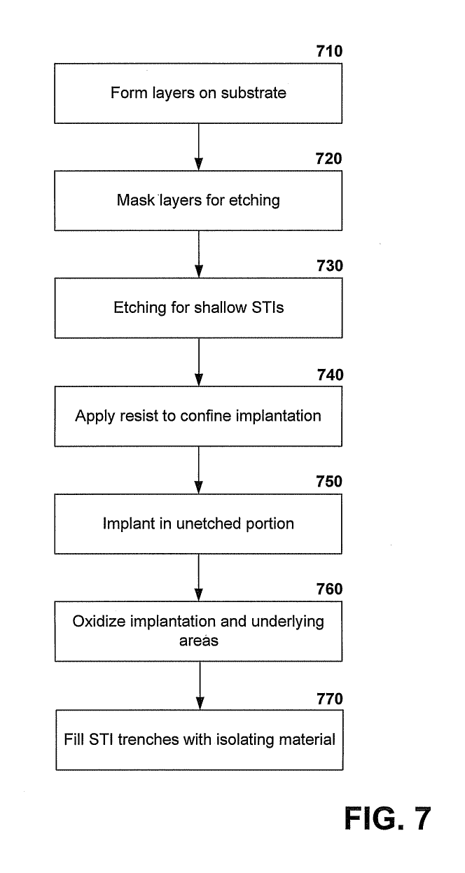

FIG. 7 presents a flow diagram illustrating an exemplary, non-limiting embodiment for extending the depth of an STI trench by utilizing implantation of Ge at the bottom of a single-trench STI and subsequently oxidizing the implanted Ge to form SiGe oxide. Hence, owing to the combination of a shallow STI trench (e.g., trench 631) with Ge implantation and SiGe oxidation a trench having properties and performance associated with a deep-trench STI can be formed without having to incur deleterious issues manifest with deep-trench STI production techniques and operation.

At 710, a plurality of layers are deposited/formed to create the basic layered structure of the SOTB device. On a base substrate (e.g., substrate 605) comprising of any suitable material (e.g., Si) a layer of SiGe is formed (e.g., layer 610). Above this layer, an Si layer (e.g., layer 615) is formed, followed by formation of thin BOX layer (e.g., thin BOX 620) and an SOI layer (e.g., SOI layer 625).

At 720, a masking layer (e.g., masking layer 630) is deposited on to the SOI layer and patterned as required to facilitate subsequent etching to form the required STI trenches (e.g., trenches 631, 632, and 633).

At 730, etching of the SOI layer, thin BOX layer, and Si layers is conducted to form the STI trenches. Etching is performed such that the STI trenches (e.g., trenches 631, 632, and 633) are of such a depth that they can be seamlessly filled with oxide thereby acting as isolation structures (note the depth of trench 631 is to be extended as described further). The respective depths of the STI shallow trenches in relation to the thicknesses of the layers through which the etching occurs (e.g., SOI layer, thin box layer, and Si layer) is determined such that while an STI shallow trench process is performed, a required amount of Si material is retained at the bottom of the STI trench to undergo implantation (e.g., region 634 in trench 631). In an embodiment, such Si material retained is in a magnitude of about 10-30 nm in height. The actual height is a function of the involved processes, such as a thickness of Si that can be implanted with Ge, and also a thickness of SiGe (and underlying region 642 as discussed below) through which oxidation can occur.

At 740 resist is applied to confine the region(s) which undergo Ge implantation. Hence, only Si material (e.g., material in region 634) at the bottom of central trench (e.g., trench 631) is to undergo Ge implantation and the remaining trenches are covered with resist (e.g., resist 635).

At 750 Ge implantation is conducted with implantation occurring in the Si material (e.g., material in region 634) at the bottom of the central trench (e.g., trench 631). Ge implantation occurs such that the Si material at the bottom of the trench comprises a required composition of SiGe. It is to be noted that the newly formed SiGe region (e.g., region 640) is effectively contiguous with SiGe material in the SiGe layer below (e.g., SiGe layer 610 region 642).

At 760, oxidation of the newly formed SiGe material at the bottom of the trench along with an underlying region of SiGe (e.g., underlying SiGe region 643) is conducted. Oxidation of the respective SiGe material (e.g., SiGe 640 and SiGe 642) results in the formation of SiGe oxide at the base of the trench (e.g., in region 650). Depending upon the various conditions of the oxidizing atmosphere, thickness of Si material retained at the bottom of the STI trench, thickness of the underlying SiGe layer, etc., the height of the SiGe oxide (e.g., in region 650) produced at the base of the trench can be of any effected amount (e.g., height H2 can be in the range of about 15-70 nm).

At 770, the STI trenches (e.g., trenches 631, 632, and 633) can be filled with any suitable material (e.g., oxide) to facilitate formation and operation of the respective isolating structures. Owing to the oxidation process, the formed region of SiGe oxide can be of the magnitude of about 50 nm and further, the inverted T-shape formed by the oxide in the STI trench (e.g., trench 631) and the SiGe oxide formed at the bottom of the STI trench (e.g., region 650) further improves the isolating properties of the STI trench in comparison with a double depth STI trench owing to the enlarged region of SiGe oxide at the bottom of STI trench 631. Owing to limitations of a deposition process to form a trench having the inverted T-shape, formation of such a structure by conventional means is limited, however, as described herein, such an inverted T-shape structure is possible when utilizing STI shallow trench formation in combination with Ge implantation and SiGe oxidation. Furthermore, the profile of the SiGe oxide region (e.g., region 650) is rounded which reduces stress at the base of the STI trench, further improving the longevity and isolation properties of the STI trench.

Fabricating a deep trench with SiGe oxidation.

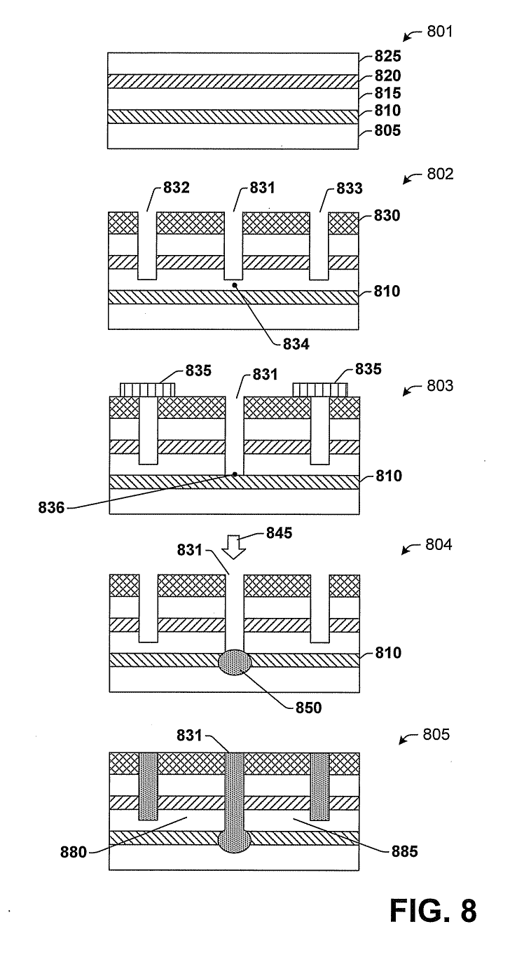

FIG. 8 illustrates an exemplary, non-limiting embodiment for formation of a SOTB device utilizing extension of a single-trench STI and subsequently oxidizing the exposed SiGe layer to form SiGe oxide, facilitating formation of a deep trench effect as part of an STI technique. As illustrated in stage 801, a plurality of layers are deposited/formed. On a substrate 805 (e.g., comprising of Si) an SiGe layer 810 is deposited. Above the SiGe layer, an Si layer 815 is formed, followed by formation of thin BOX 820 and SOI layer 825.

At stage 802, a masking layer 830 is deposited on to SOI layer 825, patterned and etched to subsequently form single-trenches 831, 832, and 833. It is to be noted that trenches 831, 832, and 833 do not extend to contact Si layer 810, rather Si material exists at the base of each trench, particularly in region 834 of trench 831.

At stage 803, trench 831 is extended by etching. Owing to etching of only trench 831 being required, resists 835 are formed over trenches 832 and 833 to prevent unnecessary etching of these trenches. Region 834 is etched such that the underlying portion 836 of SiGe layer 810 is exposed. In an exemplary, non-limiting embodiment, the SiGe layer 810 can act as an etch stop layer to the etchant utilized to remove Si region 834.

At stage 804, an oxidizing environment 845 is created with respect to trench 831. Owing to the oxidizing atmosphere, oxidation of SiGe region 836 occurs and results in the formation of SiGe oxide 850 at the base of trench 831.

At stage 805, STI trenches 831, 832, and 833 can be filled with a suitable isolating material (e.g., an oxide) to facilitate formation of the isolating trench structures. In comparison with trenches formed using a double-depth process (e.g., as shown in FIG. 2-202) the respective trenches 831, 832, and 833 can be seamlessly filled with a degree of operational consistency and repeatability as required in high volume semiconductor device manufacture. Owing to the isolation by trench 831 and oxide region 850, GP regions can operate as respective p-type or n-type regions, e.g., region 880 can be either a GP(p) region or a GP(n) region while region 885 can be the corresponding/alternate GP(p) region or GP(n) region.

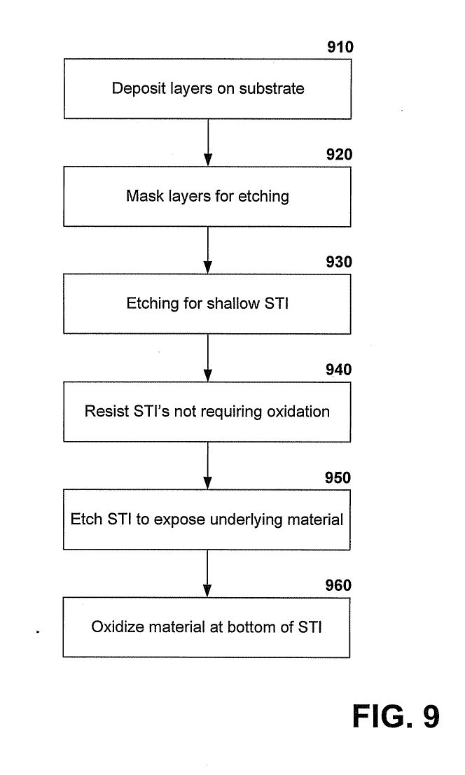

FIG. 9 presents a flow diagram illustrating an exemplary, non-limiting embodiment for extending the depth of an STI trench by oxidizing an exposed layer of SiGe oxide.

At 910, a plurality of layers are deposited/formed to create the basic layered structure of the SOTB device. On a base substrate (e.g., substrate 805) comprising of any suitable material (e.g., Si) a layer of SiGe is formed (e.g., layer 810). Above this layer, an Si layer (e.g., layer 815) is formed, followed by formation of thin BOX (e.g., thin BOX 820) and an SOI layer (e.g., SOI layer 825).

At 920, a masking layer (e.g., masking layer 830) is deposited on to the SOI layer and patterned as required to facilitate subsequent etching to form the required STI trenches (e.g., trenches 831, 832, and 833).

At 930, etching of the SOI layer, thin BOX layer, and Si layers is conducted to form the STI trenches. Etching is performed such that the STI trenches (e.g., trenches 831, 832, and 833) are of such a depth that they can be seamlessly filled with oxide thereby acting as isolation structures (note the depth of trench 831 is to be extended as described further).

At 940 resist is applied to confine the region(s) which undergo further etching. Hence, only Si material (e.g., material in region 834) at the bottom of central trench (e.g., trench 631) is to be further removed, and the other trenches are protected with resist (e.g., resist 835).

At 950 material at the bottom of the trench (e.g., material 834) is removed to expose the underlying material in the SiGe layer beneath (e.g., region 836 of layer 810). Any suitable etching process can be utilized, for example, reactive ion etching (RIE).

At 960, oxidation of the exposed SiGe material (e.g., region 836) at the bottom of the trench is performed. Oxidation of the SiGe material results in the formation of SiGe oxide at the base of the trench (e.g., in region 850). The STI trenches (e.g., trenches 831, 832, and 833) can be filled with any suitable material (e.g., oxide) to facilitate formation and operation of the respective isolating structures. Owing to the oxidation process, the formed region of SiGe oxide can be of the magnitude of about 50 nm and further, the inverted T-shape formed by the oxide in the STI trench (e.g., trench 831) and the SiGe oxide formed at the bottom of the STI trench (e.g., region 850) further improves the isolating properties of the STI trench in comparison with a double depth STI trench owing to the enlarged region of SiGe oxide at the bottom of STI trench 831. Owing to limitations of a deposition process to form a trench having the inverted T-shape, formation of such a structure by conventional means is limited, however, as described herein, such an inverted T-shape structure is possible when utilizing STI shallow trench formation in combination with SiGe oxidation. Furthermore, the profile of the SiGe oxide region (e.g., region 850) is rounded which reduces stress at the base of the STI trench, further improving the longevity and isolation properties of the STI trench.

What has been described above includes examples of the disclosed innovation. It is, of course, not possible to describe every conceivable combination of components or methodologies for purposes of describing the disclosed innovation, but one of ordinary skill in the art can recognize that many further combinations and permutations of the disclosed innovation are possible. Accordingly, the disclosed innovation is intended to embrace all such alterations, modifications and variations that fall within the spirit and scope of the appended claims.

The word “exemplary” is used herein to mean serving as an example, instance, or illustration. For the avoidance of doubt, the subject matter disclosed herein is not limited by such examples. In addition, any aspect or design described herein as “exemplary” is not necessarily to be construed as preferred or advantageous over other aspects or designs, nor is it meant to preclude equivalent exemplary structures and techniques known to those of ordinary skill in the art. Furthermore, to the extent that the terms “includes,” “has,” “contains,” and other variant thereof is used in either the description or the claims, for the avoidance of doubt, such terms can be inclusive in a manner similar to the term “comprising” as an open transition word without precluding any additional or other elements when employed in a claim.

With respect to any figure or numerical range for a given characteristic, a figure or a parameter from one range may be combined with another figure or a parameter from a different range for the same characteristic to generate a numerical range.

Other than in the operating examples, or where otherwise indicated, all numbers, values and/or expressions referring to quantities of ingredients, reaction conditions, etc., used in the specification and claims are to be understood as modified in all instances by the term “about.”

Further, while certain embodiments have been described above, it is to be appreciated that these embodiments have been presented by way of example only, and are not intended to limit the scope of the claimed subject matter. Indeed, the novel methods and devices described herein may be made without departing from the spirit of the above description. The accompanying claims and their equivalents are intended to cover such forms or modifications as would fall within the scope and spirit of the subject innovation.

In addition, it should be appreciated that while the respective methodologies provided above are shown and described as a series of acts for purposes of simplicity, such methodologies are not limited by the order of acts, as some acts can, in accordance with one or more aspects, occur in different orders and/or concurrently with other acts from that shown and described herein. For example, those skilled in the art will understand and appreciate that a methodology could alternatively be represented as a series of interrelated states or events, such as in a state diagram. Moreover, not all illustrated acts may be required to implement a methodology in accordance with one or more aspects.

What is claimed is:

1. A semiconductor device comprising:
a silicon-on-insulator (SOI) formed on a ground plane (GP), further comprising:
a buried oxide (BOX) layer formed beneath the SOI;
a first layer comprising Si:C/SiGe or Si:C formed under the BOX layer, wherein the GP is confined between the first layer and the BOX layer;
a first shallow trench, a second shallow trench and a third shallow trench located between the first shallow trench and second shallow trench, the first shallow trench, the second shallow trench and the third shallow trench extend into the SOI, BOX layer and GP, wherein the third shallow trench is further extended to touch the first layer.

2. The semiconductor device of claim 1, wherein the GP for an n-type layer is formed with phosphorous.

3. The semiconductor device of claim 1, wherein the GP for a p-type layer is formed with boron or indium.

4. The semiconductor device of claim 1, wherein the third shallow trench is extended by etching.

5. The semiconductor device of claim 1, wherein the third shallow trench is filled with isolating material and the filling extends to be contiguous with the first layer.

6. A semiconductor device comprising:
a silicon-on-insulator (SOI) formed on a ground plane (GP), further comprising:
a buried oxide layer (BOX) formed beneath the SOI;
a first layer comprising SiGe formed beneath the BOX layer, wherein the GP is between the first layer and the BOX layer;
a first shallow trench, a second shallow trench and a third shallow trench located between the first shallow trench and second shallow trench, the first shallow trench, the second shallow trench and the third shallow trench are formed in the SOI, BOX and GP, wherein Si material between the bottom of the third shallow trench and the first layer is implanted with Ge to form SiGe.

7. The semiconductor device of claim 6, wherein the SiGe at the bottom of the third shallow trench is oxidized to form SiGe oxide.

8. The semiconductor device of claim 7, wherein SiGe in the first layer beneath the SiGe at the bottom of the third shallow trench is oxidized to form SiGe oxide.

9. The semiconductor device of claim 8, wherein SiGe oxide in the first layer and the SiGe oxide at the bottom of the third shallow trench are oxidized to form a single occurrence of SiGe oxide.

10. The semiconductor device of claim 9, wherein the single occurrence of SiGe oxide is about 15-70 nm in height.

11. The semiconductor device of claim 9, wherein the third shallow trench is filled with isolating material and the filling extends to be contiguous with the single occurrence of SiGe oxide.

12. The semiconductor device of claim 11, wherein the filled third shallow trench and the single occurrence of SiGe oxide act to confine the GP.

13. The semiconductor device of claim 6, wherein the GP for an n-type layer is formed with phosphorous.

14. The semiconductor device of claim 6, wherein the GP for a p-type layer is formed with boron or indium.

15. The semiconductor device of claim 6, wherein the thickness of material between the bottom of the third shallow trench and the first layer is about 10-30 nm.

16. A semiconductor device comprising:
a silicon-on-insulator (SOI) formed on a ground plane (GP), further comprising:
a buried oxide layer (BOX) formed beneath the SOI;
an SiGe layer formed under the BOX layer, wherein the GP is between the first layer and the BOX layer;
a first shallow trench, a second shallow trench and a third shallow trench located between the first shallow trench and second shallow trench, the first shallow trench, the second shallow trench and the third shallow trench are formed in the SOI, BOX layer and GP, wherein material between the bottom of the third shallow trench and the SiGe layer is removed to expose SiGe material in the first layer and wherein the exposed SiGe material is oxidised.

17. The semiconductor device of claim 16, wherein the GP for an n-type layer is formed with phosphorous.

18. The semiconductor device of claim 16, wherein the GP for a p-type layer is formed with boron or indium.

19. The semiconductor device of claim 16, wherein the third shallow trench is filled with isolating material and the filling extends to be contiguous with the oxidized SiGe material.

20. The semiconductor device of claim 19, wherein the filled third shallow trench and the oxidized SiGe material act to confine the GP.
